(19) United States
(12) Patent Application Publication
(10) Pub. No.: US 2026/0066225 A1
(43) Pub. Date: Mar. 5, 2026

(54) Multi-Mode Inductively Coupled Plasma

(71) Applicant: Applied Materials Inc., Santa Clara, CA (US)

(72) Inventors: Yue GUO, Redwood City, CA (US); Yuhui ZHANG, Sunnyvale, CA (US); A N M Wasekul AZAD, Cupertino, CA (US); Yang YANG, Cupertino, CA (US); Kartik RAMASWAMY, San Jose, CA (US); Nicolas John BRIGHT, Mountain Lakes, NJ (US)

(21) Appl. No.: 18/825,402

(22) Filed: Sep. 5, 2024

(51) Int. Cl. H01J 37/32

(52) U.S. Cl. CPC H01J 37/3211; H01J 37/32183

(57) ABSTRACT

Methods and apparatus for inductively coupled plasma chambers allow for split parallel coil sets to be energized with the same or different RF frequencies. An ICP source may comprise a first RF power with a first frequency connected to a first coil set of the coil assembly, a second RF power with a second frequency connected to a second coil set where the first coil set has a first inner coil and a first outer coil positioned concentrically about the first inner coil, the first inner coil and the first outer coil are electrically connected in series, the second coil set has a second inner coil and a second outer coil positioned concentrically about the second inner coil, the second inner coil and the second outer coil are electrically connected in series, and the first coil set and the second coil set are electrically energized separately from each other.

### FIELD

Embodiments of the present principles generally relate to semiconductor processing of semiconductor substrates.

### BACKGROUND

Inductively coupled plasma (ICP) chambers use coils or antennas to induce RF energy into a gas disposed inside of the process volume of the chamber. The induced RF energy and gas creates plasma with a high plasma density. The coupling of the RF energy into the gas is accomplished via a magnetic field produced by the coils. The plasma can be used for etching and other processing of a wafer inside of the chamber. However, the inventors have observed that, for example, the etch rate effect of the plasma on the wafer is not always uniform in nature, possibly reducing the performance of structures formed on the wafer or even reducing yields due to the defects caused by the etch rate nonuniformity.

Accordingly, the inventors have provided methods and apparatus for improving the etch rate uniformity of inductively coupled plasma on the wafer.

### SUMMARY

Methods and apparatus for supplying RF energy to an inductively coupled plasma chamber are provided herein.

In some embodiments, a method of energizing a coil assembly of an inductively coupled plasma (ICP) chamber may comprise generating a first RF power for the ICP chamber with a first frequency to a first electrical connection of a first coil set of the coil assembly via a first match network where a second electrical connection of the first coil set is connected to a ground and the coil assembly is positioned atop the ICP chamber and generating a second RF power for the ICP chamber with a second frequency to a third electrical connection of a second coil set of the coil assembly via a second match network where a fourth electrical connection of the second coil set is connected to the ground and the second frequency is the same or different from the first frequency where the first coil set has at least one first inner coil and at least one first outer coil positioned concentrically about the at least one first inner coil, the at least one first inner coil and the at least one first outer coil are electrically connected in series, the second coil set has at least one second inner coil and at least one second outer coil positioned concentrically about the at least one second inner coil, the at least one second inner coil and the at least one second outer coil are electrically connected in series, and the first coil set and the second coil set are electrically isolated from each other.

In some embodiments, the method may further include filtering the second frequency of the second RF power from the first RF power with a first RF isolation filter positioned in series between the first match network and the first electrical connection of the first coil set or between the first match network and a source of the first RF power and filtering the first frequency of the first RF power from the second RF power with a second RF isolation filter positioned in series between the second match network and the third electrical connection of the second coil set or between the second match network and a source of the second RF power, a second electrical connection that is connected to the ground via a first current divider and where the third electrical connection is connected to the ground via a second current divider, a first current divider filter that is positioned in electrical series between the second electrical connection of the first coil set and the ground to adjust current through the first current divider and a second current divider filter that is positioned in electrical series between the fourth electrical connection of the second coil set and the ground to adjust current through the second current divider, a first capacitor that is connected between the at least one first inner coil and the at least one first outer coil and a ground where a second capacitor is connected between the at least one second inner coil and the at least one second outer coil and the ground, a first ground filter that is positioned in electrical series with the first capacitor of the first coil set and the ground, and a second ground filter that is positioned in electrical series with the second capacitor of the second coil set and the ground, a first coil set that has a plurality of sets of series connected first inner coils and first outer coils and where each set of series connected first inner coils and first outer coils are connected in parallel to each other set of the plurality of sets of series connected first inner coils and first outer coils and the second coil set has a plurality of sets of series connected second inner coils and second outer coils and where each set of series connected second inner coils and second outer coils are connected in parallel to each other set of the plurality of sets of series connected second inner coils and second outer coils, at least one first inner coil of the first coil set that is intertwined with the at least one second inner coil of the second coil set and the at least one first outer coil of the first coil set that is intertwined with the at least one second outer coil of the second coil set, a first RF power that is pulsed at a first power level and at a first pulse frequency and the second RF power is pulsed at a second power level and at a second pulse frequency where the second power level is different from the first power level, a first RF power that is pulsed with a first pulse at a first power level and a second pulse at a second power level different from the first power level, a first pulse that has a first pulse width and the second pulse has a second pulse width different from the first pulse width, a second RF power that is pulsed with a first pulse at a first power level and a second pulse at a second power level different from the first power level, and/or a first pulse that has a first pulse width and the second pulse has a second pulse width different from the first pulse width.

In some embodiments, an apparatus for supplying RF energy to an inductively coupled plasma (ICP) chamber may comprise a first coil set of a coil assembly where a first electrical connection of the first coil set is connected to a first RF power channel with a first frequency and a second electrical connection of the first coil set is connected to a ground, the first coil set has at least one first inner coil and at least one first outer coil positioned concentrically about the at least one first inner coil, and the at least one first inner coil and the at least one first outer coil are electrically connected in series and a second coil set of the coil assembly where a third electrical connection of the first coil set is connected to a second RF power channel with a second frequency and a fourth electrical connection of the second coil set is connected to the ground, the second frequency of the second RF power channel is the same or different from the first frequency of the first RF power channel, the second coil set has at least one second inner coil and at least one second outer coil positioned concentrically about the at least one second inner coil, the at least one second inner coil and the at least one second outer coil are electrically connected in series, and the second coil of the coil assembly set is electrically isolated from the first coil set of the coil assembly.

In some embodiments, the apparatus may further include a first RF isolation filter that is positioned in electrical series between the first electrical connection of the first coil set and the first RF power channel or between a first match network and the first RF power channel where the first RF isolation filter is configured to pass the first frequency and block the second frequency and a second RF isolation filter that is positioned in electrical series between the third electrical connection of the second coil set and the first RF power channel or between a second match network and the second RF power channel where the second RF isolation filter is configured to pass the second frequency and block the first frequency, a first current divider filter that is positioned in electrical series between the second electrical connection of the first coil set and the ground and configured to adjust current through a first current divider and a second current divider filter that is positioned in electrical series between the fourth electrical connection of the second coil set and the ground and configured to adjust current through a second current divider, a first ground filter that is positioned in electrical series with a first capacitor positioned between the at least one first inner coil and the at least one first outer coil of the first coil set and a ground and a second ground filter that is positioned in electrical series with a second capacitor positioned between the at least one second inner coil and the at least one second outer coil of the second coil set and the ground, at least one first inner coil of the first coil set that is intertwined with the at least one second inner coil of the second coil set and the at least one first outer coil of the first coil set is intertwined with the at least one second outer coil of the second coil set, and/or a first RF power channel and a second RF power channel that are provided by a single RF generator with a plurality of RF power channels.

In some embodiments, a non-transitory, computer readable medium having instructions stored thereon that, when executed, cause a method of energizing a coil assembly of an inductively coupled plasma (ICP) chamber to be performed, the method may comprise generating a first RF power for the ICP chamber with a first frequency to a first electrical connection of a first coil set of the coil assembly via a first match network where a second electrical connection of the first coil set is connected to a ground and the coil assembly is positioned atop the ICP chamber and generating a second RF power for the ICP chamber with a second frequency to a third electrical connection of a second coil set of the coil assembly via a second match network where a fourth electrical connection of the second coil set is connected to the ground, the second frequency the same or different from the first frequency, the first coil set has at least one first inner coil and at least one first outer coil positioned concentrically about the at least one first inner coil, the at least one first inner coil and the at least one first outer coil are electrically connected in series, the second coil set has at least one second inner coil and at least one second outer coil positioned concentrically about the at least one second inner coil, the at least one second inner coil and the at least one second outer coil are electrically connected in series, and the first coil set and the second coil set are electrically isolated from each other.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method of energizing a coil assembly of an inductively coupled plasma (ICP) chamber in accordance with some embodiments of the present principles.

FIG. 2 depicts a schematic view of a coil energizing system in accordance with some embodiments of the present principles.

FIG. 3 depicts a schematic view of parallel sets of split coil pairs for an RF power source channel in accordance with some embodiments of the present principles.

FIG. 4 depicts a top-down view of a planar split coil pair for an RF power source channel in accordance with some embodiments of the present principles.

FIG. 5 depicts a top-down view of a planar split coil trio for an RF power source channel in accordance with some embodiments of the present principles.

FIG. 6 depicts a cross-sectional view of a planar split coil assembly in accordance with some embodiments of the present principles.

FIG. 7 depicts a side view of a vertical split coil assembly in accordance with some embodiments of the present principles.

FIG. 8 depicts graphs of waveform examples for a dual channel RF power source in accordance with some embodiments of the present principles.

FIG. 9 depicts a cross-sectional view of an inductively coupled plasma (ICP) chamber in accordance with some embodiments of the present principles.

FIG. 10 depicts a schematic view of a split coil assembly in accordance with some embodiments of the present principles.

FIG. 11 depicts a schematic view of a coil energizing system in accordance with some embodiments of the present principles.

FIG. 12 depicts a schematic view of a coil energizing system with parallel inner and outer coil sets in accordance with some embodiments of the present principles.

FIG. 13 depicts a schematic view of a coil energizing system with an inner coil and outer coil electrically connected in a reverse order in accordance with some embodiments of the present principles.

FIG. 14 depicts a schematic view of possible filter positions within a coil energizing system in accordance with some embodiments of the present principles.

FIG. 15 depicts a schematic view of a single filter positioned in a coil energizing system in accordance with some embodiments of the present principles.

FIG. 16 depicts a schematic view of two filters positioned in a coil energizing system in accordance with some embodiments of the present principles.

FIG. 17 depicts a schematic view of three filters positioned in a coil energizing system in accordance with some embodiments of the present principles.

FIG. 18 depicts a schematic view of a bridge capacitor positioned in a coil energizing system in accordance with some embodiments of the present principles.

FIG. 19 depicts a schematic view of another coil energizing system configuration with divider circuits in accordance with some embodiments of the present principles.

FIG. 20 depicts a schematic view of possible filter positions within another coil energizing system configuration with divider circuits in accordance with some embodiments of the present principles.

FIG. 21 depicts a schematic view of yet another coil energizing system configuration with divider circuits in accordance with some embodiments of the present principles.

FIG. 22 depicts a schematic view of possible filter positions within another coil energizing system configuration with divider circuits in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and apparatus provide highly tunable inductive coupling for inductive coupling plasma (ICP) chambers. A plurality of RF power source channels is used in conjunction with a split coil assembly that has electrically isolated split coil sets for each of the plurality of RF power sources. Isolation filtering prevents power back feeding from the other RF power source channels due to inductive coupling between each of the electrically isolated split coil sets. The isolation filtering also has the advantage of reducing/eliminating crosstalk between the RF power source channels to prevent corruption of the RF power. Additional inductive coupling tuning can be achieved by using two or more electrically paralleled split coils within each split coil set. Further tuning flexibility can also be achieved by filtering the current divider capacitor current and/or the ground capacitor current. The plurality of RF power source channels can be provided by a single RF generator with multiple channels or multiple RF generators operating in a synchronized mode. The plurality of RF power source channels allows for the same or different frequencies to be used for each RF power source channel, yielding greater flexibility in choosing frequencies to avoid crosstalk between the channels. The use of multiple RF generators, in addition, advantageously allows for multi-mode and multi-level operation with power level changes with each pulse during pulsed RF generator operation that are not possible using a single RF generator.

In a conventional design, for example, four split coil pairs (each split coil pair having one outer coil and one inner coil) may be electrically connected in parallel. A single power source supplies RF power first to all of the parallel outer coils and then to all of the parallel inner coils and then to ground. A current divider capacitor may be positioned between the ground and the parallel connected inner coils. The current divider capacitor is typically placed inside of the match network of the power source so that the current divider capacitor can be controlled easily. Each split coil pair includes an outer coil connected in series with an inner coil and a ground capacitor connected between the outer coil and the inner coil and ground. The inventors have observed, however, that the conventional design produces an “M” shaped uniformity profile on the substrate undergoing processing. The inventors have discovered that by using a plurality of electrically isolated RF power source channels with each channel supplying power to one or more split coil pairs (electrically connected in parallel if a plurality of split coil pairs are used) along with isolation filters, ground filters, and current divider filters, more flexibility and control are achieved over the inductive coupling, producing higher levels of uniformity not achievable with conventional designs.

The present techniques provide smooth power transitions with match networks staying near the tuned positions with minimal moves during pulsing, minimizing instabilities. Fast pulsing is supported with less reflected power, allowing for higher power coupling efficiency. Larger operation windows and greater flexibility with more controllable current ratios at different power levels to reduce the M-shaped radial ion density distribution further improve the etch rate uniformity on the surfaces of the substrates during processing. The plurality of RF power source channels in conjunction with the split coil assembly provides the greatest amount of flexibility and precise ion density control for ICP chambers to increase process uniformity. The techniques are multi-modal in that various combinations of inner coil and outer coil current ratios can be achieved to improve the uniformity. The techniques can also be used to provide a multi-level pulsing plasma source. Power may be applied to the outer coil first and then into the inner coil or into the inner coil first and then into the outer coil to provide additional flexibility and control for improved uniformity. Filters may be added in series with current divider capacitors and/or split coil ground capacitors to improve current ratio tunability and isolation. Filters can also be used for channel isolation and/or for tunability improvements. Filter types used in the present techniques may be low pass, high pass, bandpass, and/or bandstop/notch, and the like to allow or block selected frequencies for channel isolation and/or current ratio tunability.

Two or more RF generators (or a generator with multi output channels) with the same or different center frequencies can be used with each RF generator having a frequency range variability (e.g., 5% or 10% variability range centered at a given frequency). RF filters may be used before and/or after the match networks to block power coupling feedback and to also reduce crosstalk between RF power source channels. The frequency range, impedances, and circuits can be optimized to further reduce the crosstalk between RF power source channels. Multiple RF generators can be synchronized to a signal from an external controller or one of the other RF generators (e.g., master/slave). The present techniques are also compatible with various ICP coil designs such as one or more coils disposed in a flat/planar or vertical antenna structure and with or without a current ratio control. The split coils of the split coil assembly provide independent and precise control and multiple RF power source channels provide for multiple state pulsing and the like. Different current ratios can be combined to change the radial ion density distribution to further improve, for example, the etch rate uniformity.

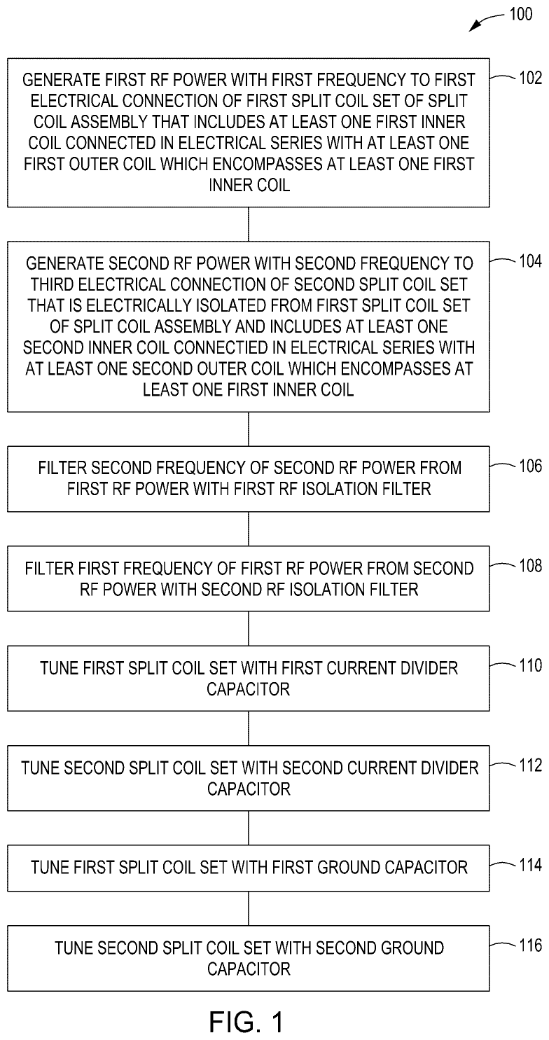

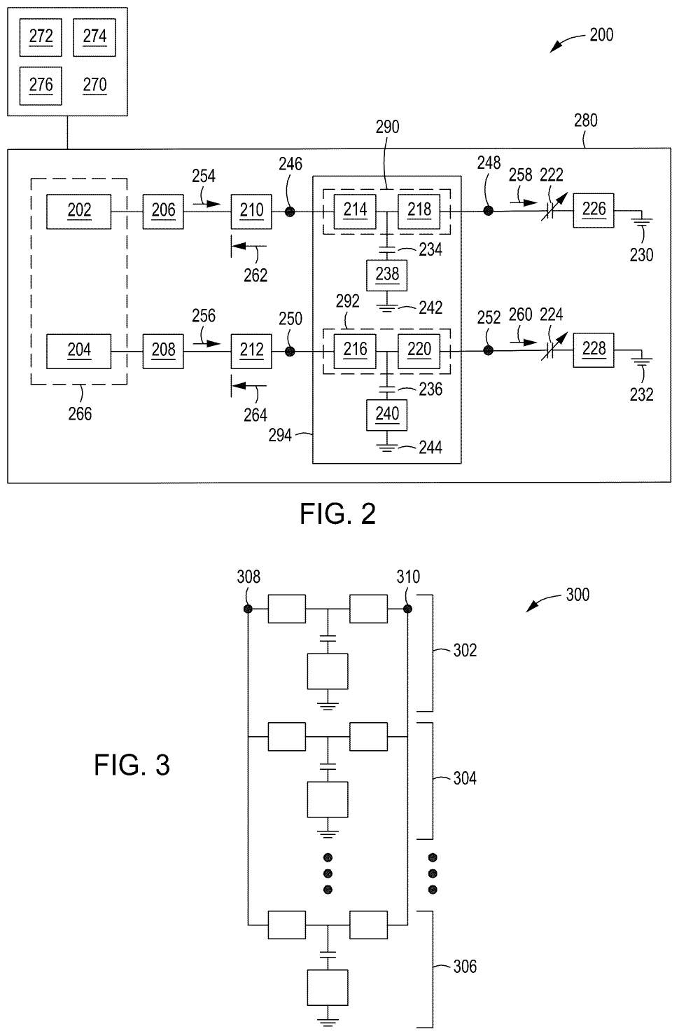

FIG. 1 is a method of energizing a split coil assembly of an ICP chamber. The method is applicable to any number of RF power source channels and any number of respective split coil sets electrically connected to an RF power source. For the sake of brevity, examples use two RF power source channels, but are not meant to be limiting. A split coil set may include a single outer coil in series with a single inner coil or may include a plurality of pairs of outer coils and inner coils electrically connected in parallel. The RF power source channels may be first directly connected to the outer coils which are then serially connected to the inner coils or may be first directly connected to the inner coils which are then serially connected to the outer coils. References are made to FIG. 2 which depicts an ICP generation system 280 with a controller 270 in discussions of the method 100.

In block 102, a first RF power source channel 202 with a first frequency generates RF power including a first input current 254 to a first electrical connection 246 of a first split coil set 290 of a split coil assembly 294 that includes one or more first outer coil 214 connected in electrical series with one or more first inner coil 218, as depicted in a view 200 of FIG. 2. The first outer coil 214 is physically positioned concentrically around the first inner coil 218 to substantially encompass the first inner coil 218. The split coil set has a first split coil ground 242 electrically tied to the serial connection between an outer coil and the inner coil. A first ground capacitor 234 is serially connected between the serial connection of the outer and inner coils and the first split coil ground 242. In some embodiments, a second electrical connection 248, at the other end of the series connections is connected to a first ground 230. In some embodiments, the first RF power source channel 202 may be connected first to an outer coil with an inner coil having a ground connection at the end of the series connection (as depicted in FIG. 2). In some embodiments, the first RF power source channel 202 may be connected first to an inner coil with an outer coil having a ground connection at the end of the series connection (the first inner coil 218 connected to first electrical connection 246 and first outer coil 214 connected to the first inner coil 218 and then to first ground 230). In some embodiments, a first match network 206 may be positioned in electrical series between the first RF power source channel 202 and the first electrical connection 246.

In block 104, a second RF power source channel 204 with a second frequency, the same or different from the first frequency of the first RF power source channel 202, generates RF power including a second input current 256 to a third electrical connection 250 of a second split coil set 292 that is electrically isolated from the first split coil set 290 of the split coil assembly 294 and includes one or more second outer coil 216 connected in electrical series with one or more second inner coil 220. The second outer coil 216 is physically positioned concentrically to substantially encompass the second inner coil 220. The split coil set has a second split coil ground 244 electrically tied to the serial connection between an outer coil and the inner coil. A second ground capacitor 236 is serially connected between the serial connection of the outer and inner coils and the second split coil ground 244. In some embodiments, a fourth electrical connection 252, at the other end of the series connections is connected to a second ground 232. In some embodiments, the second RF power source channel 204 may be connected first to an outer coil with an inner coil having a ground connection at the end of the series connection (as depicted in FIG. 2).

In some embodiments, the second RF power source channel 204 may be connected first to an inner coil with an outer coil having a ground connection at the end of the series connection (the second inner coil 220 connected to third electrical connection 250 and second outer coil 216 connected to the second inner coil 220 and then to second ground 232). In some embodiments, a second match network 208 may be positioned in electrical series between the second RF power source channel 204 and the third electrical connection 250. The first split coil set 290 and the second split coil set 292 of the split coil assembly 294 are electrically isolated from each other. The present techniques are not limited to only two RF power source channels. Any number of RF power source channels and respective split coil sets can be used in a split coil assembly. The RF power source channels 266 may be generated by a single RF generator or by separate RF generators that are synchronized (e.g., master/slave or by external synchronization source, etc.).

In block 106, the second frequency of the second RF power source channel 204 is filtered from the first RF power source channel 202 with a first RF isolation filter 210 to isolate the first RF power source channel 202 from the damaging effects of power feedback and/or crosstalk from the second RF power source channel 204 (e.g., feedback current 262). Although, the first split coil set 290 and the second split coil set 292 of the split coil assembly 294 are electrically isolated, the coils can be inductively coupled to each other, allowing crosstalk from the coils and power from different frequencies to be fed back to other non-originating RF power source channels. The first RF isolation filter 210 is positioned in series between the first match network 206 and the first electrical connection 246 of the first split coil set 290 and/or between the first match network 206 and the first RF power source channel 202.

In block 108, the first frequency of the first RF power source channel 202 is filtered from the second RF power source channel 204 with a second RF isolation filter 212 to isolate the second RF power source channel 204 from the damaging effects of power feedback and/or crosstalk from the first RF power source channel 202 (e.g., feedback current 264). Although, the second split coil set 292 and the first split coil set 290 of the split coil assembly 294 are electrically isolated, the coils can be inductively coupled to each other, allowing crosstalk from the coils and power from different frequencies to be fed back to other non-originating RF power source channels. The second RF isolation filter 212 is positioned in series between the second match network 208 and the third electrical connection 250 of the second split coil set 292 and/or between the second match network 208 and the second RF power source channel 204. As noted above, any number of RF power source channels may be used and, as such, any number of RF isolation filters may also be used to block any number of frequencies from reaching back to the other non-originating RF power source channels.

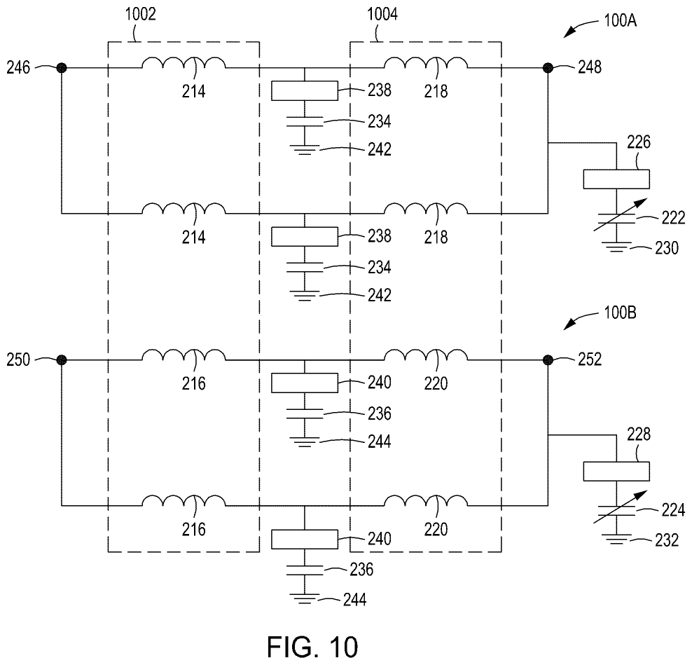

FIG. 10 depicts an electrical schematic of a first split coil set 1000A and a second split coil set 1000B with each split coil set having two split coils in parallel with a common ground and a common power input connection. The coils, represented by inductors, create magnetic field lines as power flows through the coils. The magnetic field lines induce current to flow in adjacent coils affected by the magnetic fields (inductively coupled coils 1002 (e.g., outer coils) and inductively coupled coils 1004 (e.g., inner coils)). The induced current will have the same frequency as the coils that caused the induced current which may not be the same frequency as the current being supplied to the coils. In some embodiments, the isolation filters of a first split coil set can be selected to block all frequencies other than the RF power source channel supplying power directly to the first split coil set. In some embodiments, the isolation filters of the first split coil set can be selected to block a certain frequency range that includes the frequency of an RF power source supplying power to a second split coil set. For example, if a first RF power source channel 202 supplies a frequency of 13 MHz to a first electrical connection 246 and a second RF power source channel 204 supplies a frequency of 27 MHz to a third electrical connection 250, a first ground capacitor 234 and a first current divider filter 226 may be used to block the 27 MHz frequency of the second RF power source.

In block 110, the first split coil set 290 is tuned by adjusting a first output current 258 using a first current divider capacitor 222 positioned between the second electrical connection 248 and the first ground 230 and in series with a first current divider filter 226 (the first current divider filter 226 may be placed before or after the first current divider capacitor 222). The first current divider capacitor 222 is used to adjust a first current ratio of the first split coil set 290. The first current ratio is the first input current 254 divided by the first output current 258. The current ratio can be used to adjust the plasma density which affects the uniformity of the process in the process volume of the ICP chamber and provides uniformity control. In some embodiments, the first current divider filter 226 may be used to filter out current based on frequency and the like (e.g., to block current of frequencies associated with a second RF current generated by a second RF power source channel 204 to prevent crosstalk, unwanted leakage current to ground, and interference, etc.). The first current divider capacitor 222 may be fixed or may be variable in value. In some embodiments, the first current divider capacitor 222 may be adjusted directly by the controller 270 and/or by the first match network 206 which may also be controlled by the controller 270. In some embodiments, the first current divider capacitor 222 may have a capacitance value of approximately 1 pF to approximately 3000 pF. In some embodiments where the first split coil set 290 has more than one split coil in parallel, the first current divider capacitor 222 will control the current flow through all of the parallel split coils.

In block 112, the second split coil set 292 is tuned by adjusting a second output current 260 using a second current divider capacitor 224 positioned between the fourth electrical connection 252 and the second ground 232 and in series with a second current divider filter 228 (the second current divider filter 228 may be placed before or after the second current divider capacitor 224). The second current divider capacitor 224 is used to adjust the second current ratio of the second split coil set 292. The second current ratio is the second input current 256 divided by the second output current 260. The current ratio can be used to adjust the plasma density which affects the uniformity of the process in the process volume of the ICP chamber and provides uniformity control. In some embodiments, the second current divider filter 228 may be used to filter out current based on frequency and the like (e.g., to block current of frequencies associated with the first RF current generated by the first RF power source channel 202 to prevent crosstalk, unwanted leakage current to ground, and interference, etc.). The second current divider capacitor 224 may be fixed or may be variable in value. In some embodiments, the second current divider capacitor 224 may be adjusted directly by the controller 270 and/or by the second match network 208 which may also be controlled by the controller 270. In some embodiments, the second current divider capacitor 224 may have a capacitance value of approximately 1 pF to approximately 3000 pF. In some embodiments where the second split coil set 292 has more than one split coil in parallel, the second current divider capacitor 224 will control the current flow through all of the parallel split coils.

In block 114, the first split coil set 290 is tuned using a first ground capacitor 234 electrically connected between the series connection of the first outer coil 214 and the first inner coil 218 and the first split coil ground 242 and in series with the first ground filter 238. In some embodiments, the first ground filter 238 may be used to assist in reducing crosstalk and increasing isolation by allowing adjustment of the current flow to ground based on the frequency of the current and the like (e.g., filtering frequencies to prevent crosstalk with another RF power source channel not directly connected to the first split coil set 290, etc.). In block 116, the second split coil set 292 is tuned using a second ground capacitor 236 electrically connected between the series connection of the second outer coil 216 and the second inner coil 220 and the second split coil ground 244 and in series with the second ground filter 240. In some embodiments, the second ground filter 240 may be used to assist in reducing crosstalk and increasing isolation by allowing adjustment of the current flow to ground based on the frequency of the current and the like (e.g., filtering frequencies to prevent crosstalk with another RF power source channel not directly connected to the second split coil set 292, etc.).

The controller 270 of the ICP generation system 280 may be used to perform the above tuning aspects of the present techniques, singly, in groups, or in unison and the like, and/or incorporate feedback from the ICP chamber processes and/or metrology results to adjust the plasma generated by the ICP generation system 280 to improve ion density and process uniformity on the substrates. The controller 270 may also be used, for example, to adjust the current ratios (current into load divided by current out of load to ground) and/or filters for each split coil set and/or RF power source channels to optimize plasma density in the ICP chamber. The controller 270 controls the operation of the ICP generation system 280 using a direct control or alternatively, by controlling the computers (or controllers) associated with the ICP generation system 280. In operation, the controller 270 enables data collection and feedback to optimize performance of the ICP generation system.

The data collection may include metrology data relating to aspects of the substrate processing which is used to alter the process recipe by the controller to enhance subsequent substrate processing and the like. The controller 270 generally includes a Central Processing Unit (CPU) 272, a memory 274, and a support circuit 276. The CPU 272 may be any form of a general-purpose computer processor that can be used in an industrial setting. The support circuit 276 is conventionally coupled to the CPU 272 and may comprise a cache, clock circuits, input/output subsystems, power supplies, and the like. Software routines, such as used in the methods and/or apparatus as described above may be stored in the memory 274 and, when executed by the CPU 272, transform the CPU 272 into a specific purpose computer (controller 270). The software routines may also be stored and/or executed by a second controller (not shown) that is located remotely from the ICP generation system 280.

The memory 274 is in the form of computer-readable storage media that contains instructions, when executed by the CPU 272, to facilitate the operation of the semiconductor processes and equipment. The instructions in the memory 274 are in the form of a program product such as a program that implements the apparatus of the present principles. The program code may conform to any one of a number of different programming languages. In one example, the disclosure may be implemented as a program product stored on a computer-readable storage media for use with a computer system. The program(s) of the program product define functions of the aspects. Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the substrate heating system described herein, are aspects of the present principles.

FIG. 3 depicts a split coil set 300 with any number of parallel split coils for a single RF power source channel. Two or more split coil sets make up a split coil assembly (see, e.g., FIG. 2, first split coil set 290 and second split coil set 292 make up split coil assembly 294). A first split coil set 302 is electrically in parallel with a second split coil set 304 and so on to an Nth split coil set 306. The split coil assembly of the present principles is not limited by the number of parallel split coils in each of the split coil sets for each of the RF power source channels. In the example of FIG. 3, a first electrical connection 308 would be connected to a RF power source channel and a second electrical connection 310 would be connected to a ground and may have an intervening current divider capacitor and/or a ground filter and the like. Each pair of coils of a split coil in a split coil set may be connected in series either with an outer coil connected to the first electrical connection 308 and then to an inner coil and then to the second electrical connection and/or with an inner coil connected to the first electrical connection 308 and then to an outer coil and then to the second electrical connection and the like.

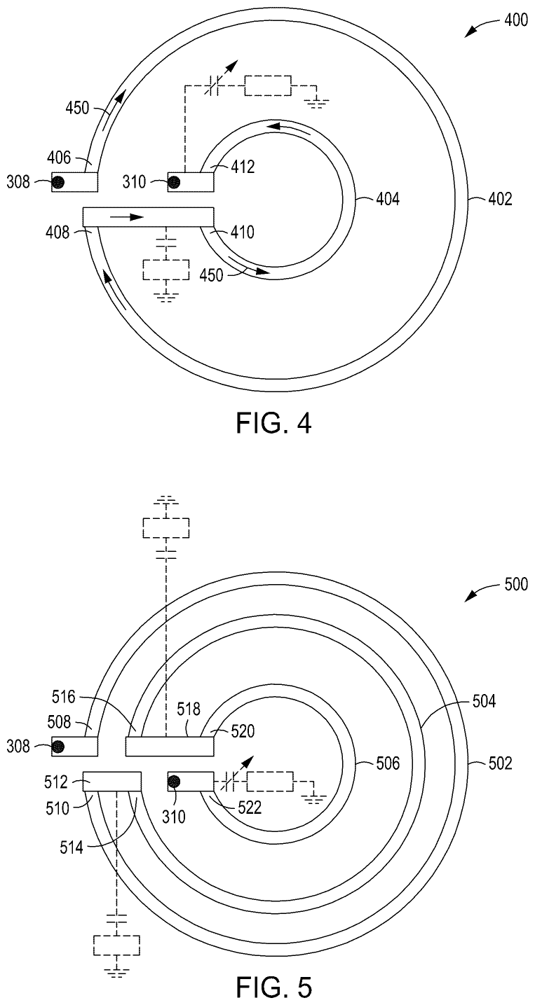

FIG. 4 depicts a top-down view of a split coil 400 that may be used in a split coil assembly per the present techniques. An outer coil 402 is connected at a first outer coil end 406 to the first electrical connection 308 that receives RF power from an RF power source channel. The outer coil 402 may have one or more windings (only one winding depicted in FIG. 4). A second outer coil end 408 of the outer coil 402 is connected in series with a first inner coil end 410. The electrical junction between the outer coil 402 and the inner coil 404 is grounded (may be grounded via a ground filter and/or a ground capacitor and the like). A second inner coil end 412 is connected to the second electrical connection 310 (which is connected to ground and may be connected to ground via a current divider capacitor and/or a current divider filter). The inner coil 404 may have one or more windings (only one winding depicted in FIG. 4). More than one split coil 400 may be electrically connected in parallel to form a split coil set for a single RF power source channel. In some embodiments, as depicted in FIG. 4, the inner and outer coils are connected such that the current flow 450 in each coil has an opposite flow direction (outer coil has current flow in clockwise direction and inner coal has current flow in counterclockwise direction). In some embodiments, the second outer coil end 408 may be connected to the second inner coil end 412 and the second electrical connection 310 may be connected to the first inner coil end 410. The current flow 450 will then be in the same clockwise direction for both coils. Other embodiments may be configured to produce counterclockwise current flow direction in both coils or counterclockwise current flow direction in the outer coil with clockwise current flow direction in the inner coil and the like to improve plasma density uniformity.

FIG. 5 depicts a top-down view of a split coil 500 that may be used in a split coil assembly per the present techniques. The split coil 500 has an outer coil 502, a middle coil 504, and an inner coil 506, all connected in series with a ground between each of the coils. Any number of radially concentric coils can be used with the present techniques. The order of the coils connected in the series can be altered under the present principles and the example of FIG. 5 is not meant to be limiting. In addition, any number of coils may be connected in series and the three coils of the example of FIG. 5 is not meant to be limiting. An outer coil 502 is connected at a first outer coil end 508 to the first electrical connection 308 that receives RF power from an RF power source channel. The outer coil 502 may have one or more windings (only one winding depicted in FIG. 5). A second outer coil end 510 of the outer coil 502 is connected in series to a first middle coil end 514. The electrical junction 512 between the outer coil 502 and the middle coil 504 is grounded (may be grounded via a ground filter and/or a ground capacitor and the like). A second middle coil end 516 is connected to a first inner coil end 520. The middle coil 504 may have one or more windings (only one winding depicted in FIG. 5). The electrical junction 518 between the middle coil 504 and the inner coil 506 is grounded (may be grounded via a ground filter and/or a ground capacitor and the like). A second end 522 of the inner coil 506 is connected to the second electrical connection 310 (which is connected to ground and may be connected to ground via a current divider capacitor and/or a current divider filter). The inner coil 506 may have one or more windings (only one winding depicted in FIG. 5). More than one split coil 500 may be electrically connected in parallel to form a split coil set for a single RF power source channel. As described above for FIG. 4, some embodiments may vary coil connections to alter the current flow direction in each of the coils (inner, middle, outer) to improve plasma density uniformity.

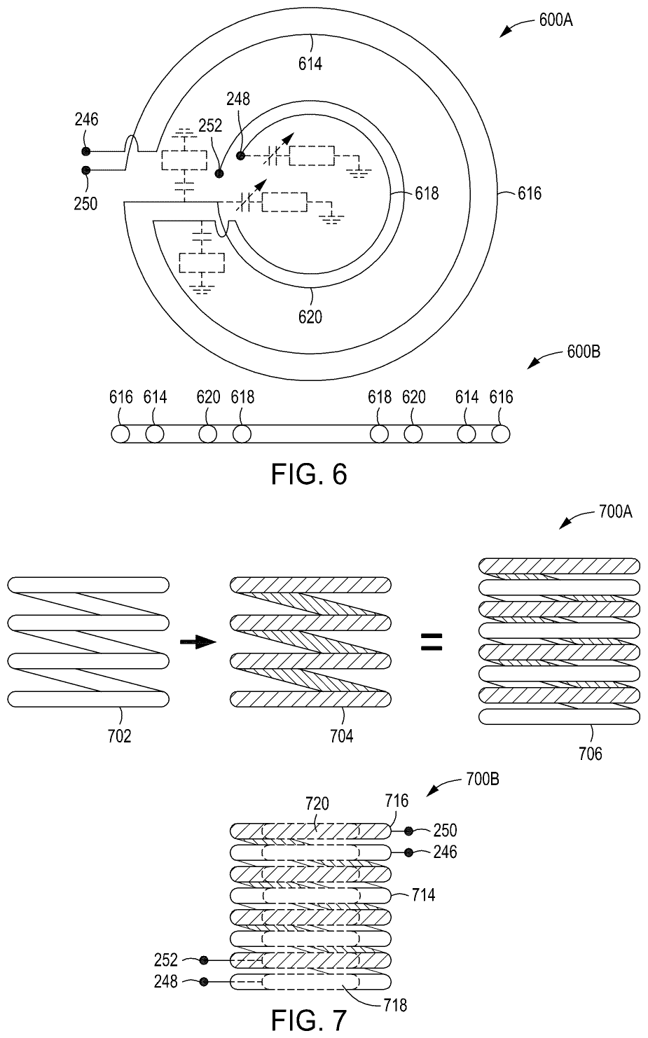

FIG. 6 depicts a top-down view 600A of a planar split coil assembly with intertwined planar split coil sets. The planar split coil assembly may be used as the split coil assembly 294 of FIG. 2. Single-loop windings are depicted in FIG. 6, but additional loops can be formed by spiraling (or other patterns) the windings inwardly or outwardly. The windings of the first split coil set 290 of the split coil assembly 294 include an outer coil 614 and an inner coil 618 connected in series with a ground at the connection point. One end of the outer coil 614 is connected to the first electrical connection 246 (first RF power source channel 202) and the end of the inner coil 618 is connected to the second electrical connection 248 (connected to ground). The windings of the second split coil set 292 of the split coil assembly 294 include an outer coil 616 and an inner coil 620 connected in series with a ground at the connection point. One end of the outer coil 616 is connected to the third electrical connection 250 (second RF power source channel 204) and the end of the inner coil 620 is connected to the fourth electrical connection 252 (connected to ground). A cross-sectional view 600B depicts that the example of the split coil assembly 294 of FIG. 6 is planar. In some embodiments, both RF power source channels may be fed into the inner coils of the respective split coil sets first (rather than the outer coils) with the outer coils connected to ground (with or without a current divider capacitor). In some embodiments, a first RF power source channel may be connected first to the inner coils while a second RF power source channel may be connected first to the outer coils. Any combination is possible with the present techniques. The outer coils of both coil sets are intertwined together, and the inner coils of both coil sets are intertwined together. As described above for FIG. 4, some embodiments may vary coil connections to alter the current flow direction in each of the coils (inner, middle, outer) to improve plasma density uniformity.

FIG. 7 depicts a side-view 700A of how vertically wound coils for a first split coil 702 and vertically wound coils for a second split coil 704 are intertwined together while maintaining electrical isolation to form intertwined split coil sets 706. The side-view 700B depicts an intertwining example of a first vertical split coil set with a first outer coil 714 and a first inner coil 718 intertwined with a second vertical split coil set with a second outer coil 716 and a second inner coil 720. The first vertical split coil set is connected to the first electrical connection 246 (first RF power source channel 202) with the other end of the series connection connected to the second electrical connection 248 (connected to ground). The second vertical split coil set is connected to the third electrical connection 250 (second RF power source channel 204) with the other end of the series connection connected to the fourth electrical connection 252 (connected to ground). The outer coils of both coil sets are intertwined together, and the inner coils of both coil sets are intertwined together.

The present techniques allow for substantial flexibility by using a plurality of RF power source channels, current dividers, and filters. One of the challenges with energizing a plasma load is that the match networks must constantly adjust to compensate for load impedance changes (ICP chamber). The loads change not only when frequencies change but also when RF power levels change. Pulsing an RF power source at different power levels is not practical, as the match networks are not given enough time to adjust to the ever-changing load impedances for the different RF power levels. When the match networks cannot fully compensate for the load impedance, harmful amounts of reflected power can damage the RF power source and, at a minimum, power transfer efficiency is substantially reduced. The present techniques overcome the challenges by using a plurality of electrically isolated split coil sets in a split coil assembly. For example, each RF power source channel can have the same or a unique RF frequency. The frequencies of each of the RF power source channels can then be selected to provide reduced crosstalk and power feedback from the inductive coupling between the split coil sets of the split coil assembly. For example, a first RF power source channel may operate at 13.56 MHz and a second RF power source channel may operate at 27 MHz, allowing for superior filtering of both frequencies from each other and allowing for a 5% or 10% operating variability range without issues. In some embodiments, the two or more RF generators may be used with the same or different center frequencies ranging from approximately 100 kHz to approximately 250 MHz. In some embodiments, the frequencies may be 2 MHz, 13.56 MHz, 27 MHz, or 40 MHz, and the like.

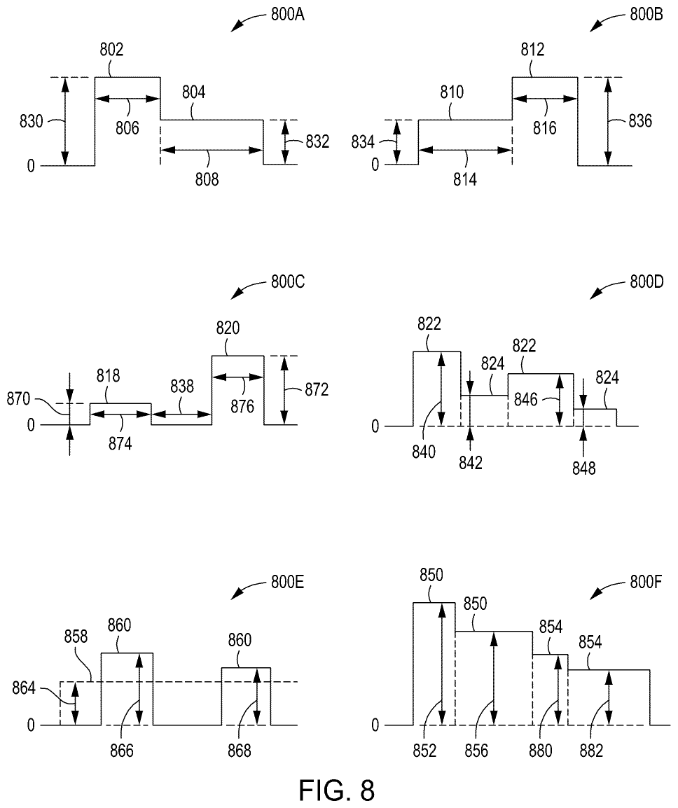

FIG. 8 depicts graphs of waveforms that are achievable with the present methods and apparatus. In some embodiments, the pulse frequency may be from approximately 10 kHz to approximately 100 kHz and the like and may be adjusted the same or differently for each RF power source channel. The examples depicted, however, are not meant to be limiting but to depict the RF power delivery flexibility that can be achieved for both pulsed and continuous wave RF power sources. The plurality of RF power source channels may be pulsed in phase or out of phase or run continuously. The flexibility of multiple RF power source channels allows for optimization by selecting a particular RF power source channel that provides the lowest reflected power (most efficient power transfer) from the impedance load at a given level, maximizing the power transfer efficiency on a pulse by pulse or continuous wave basis. Graph 800A depicts a first RF power source channel 802 being pulsed to a first power level 830 for a first duration 806 (pulse width) and a second RF power source channel 804 being pulsed to a second power level 832, less than the first power level 830, and for a second duration 808 (pulse width) greater than the first duration 806. With a traditional single RF power source channel stepping from a high power level to a low power level between pulses may cause problems. The plasma condition changes at each level which also changes the load impedance. Typically, the match network of the single RF power source channel cannot tune fast enough to provide stable output at each level for each pulse. The load impedance drops going from high to low and the match network cannot keep up with the impedance drop. Having a plurality of RF power source channels allows each channel to tune to a level, providing stable power output that matches the load impedance for each power level.

Graph 800B depicts a first RF power source channel 810 being pulsed to a first power level 834 for a first duration 814 (pulse width) and a second RF power source channel 812 being pulsed to a second power level 836, greater than the first power level 834, and for a second duration 816 (pulse width) less than the first duration 806. Each RF power source channel can provide different RF power levels and for different durations without requiring the respective match networks to alter load impedance settings. A conventional single RF power source channel cannot provide a low to high output pulse change. With the present techniques, a low to high output pulse change is now possible using a plurality of RF power source channels for the respective output power levels of each pulse. Graph 800C depicts a first RF power source channel 818 being pulsed to a first power level 870 for a first duration 874 (pulse width) and a second RF power source channel 820 being pulsed to a second power level 872, greater than the first power level 870, and for a second duration 876 (pulse width) with an off state with an off duration 838 between pulses from the RF power channels.

Graph 800D depicts a first RF power source channel 822 with a first pulse power level 840 followed by a second RF power source channel 824 with a second pulse power level 842 followed by the first RF power source channel 822 with a third pulse power level 846 followed by the second RF power source channel 824 with a fourth pulse power level 848. By alternating sources for each pulse, each RF power source channel has sufficient time for the respective match network to adjust for the different power levels (power levels change for every other pulse and are intermixed with the second RF power source channel pulses which also change every other pulse). Graph 800E depicts a first RF power source channel 858 operating at a continuous wave level 864 while a second RF power source channel 860 is pulsed at a first power level 866 and then at a second power level 868 with an off state in between. Graph 800F depicts a first RF power source channel 850 pulsing at a first RF power level 852 and then with a second RF power level 856 with a different duration (pulse width), lower than the first RF power level 852. A second RF power source channel 854 follows the pulsing of the first RF power source channel 850 by pulsing at a lower level at a third RF power level 880 with a duration different from the other pulse durations followed by a pulse at a fourth RF power level 882, lower than all other RF power levels. The above power delivery examples are not meant to be limiting but to show the flexibility of multiple RF power source channels that are also able to operate in multiple different states to alter both power levels and/or pulse duration and/or to operate in continuous wave modes (multi-modal and multi-level RF power source channels).

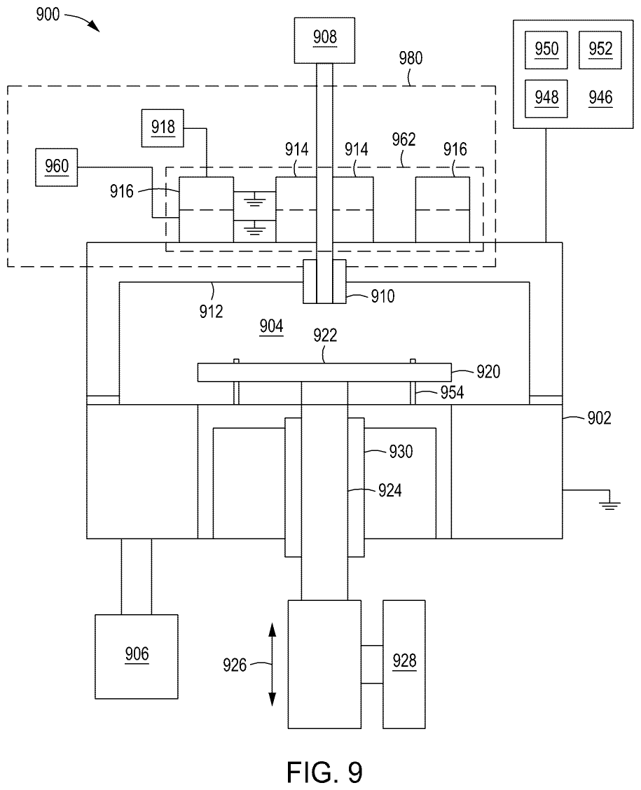

The methods and apparatus of the present principles work with single wafer reactors and twin wafer reactors and the like. FIG. 9 depicts a schematic side view of an example of an ICP chamber 900 in which the present techniques are applicable but is not meant to be limiting. The ICP chamber 900 has a flat lid 912 that may be formed from an aluminum nitride or aluminum oxide-based material. The ICP chamber 900 includes chamber walls 902 that enclose an internal process volume 904 where substrate processing occurs. The ICP chamber 900 also includes a pumping system 906 to control the pressure within the ICP chamber 900 and to expel unwanted gases before, during, or after a substrate has been processed. The pumping system 906 may also include a throttling gate valve to assist in maintaining the pressure within the ICP chamber 900. In some instances, the pumping system 906 may also include a roughing pump for fast pump down and a turbomolecular pump for higher vacuum pressures.

A gas delivery system 908 provides process gases into the internal process volume 904 through a nozzle 910. The gas delivery system 908 may include showerheads, gas rings, and/or nozzles and the like. In some embodiments, plasma is inductively coupled in the internal process volume 904 using a split coil assembly 962 of the present principles with dual split coil antennas that include a plurality of intertwined inner coil sets 914 and a plurality of intertwined outer coil sets 916. Plasma coupling power is provided by a first RF plasma source 918 with a first frequency and a second RF plasma source 960 with a second frequency. The RF plasma sources may be generated by a single multi-channel RF generator or two separate RF generators that are synchronized. The first RF plasma source 918 may provide a first frequency of approximately 100 kHz to approximately 250 MHz and the second RF plasma source 960 may provide a second frequency of approximately 100 kHz to approximately 250 MHz with the same frequency or with a frequency different from the first frequency of the first RF plasma source 918. The supplied RF power by either of the first or second RF plasma sources may each be continuous and/or pulsed. The first RF plasma source 918 and/or the second RF plasma source may also include one or more RF match networks positioned between the RF sources and the split coil assembly 962 for adjusting impedances. The split coil assembly 961 may also include various filters as described above for isolation between RF sources and/or for tunability of the split coil assembly 962 to increase uniformity of processes performed on the substrate. In some embodiments, more than two RF sources may be used.

A pedestal 920 includes an upper portion 922 with lift pins 954 and a lower portion 924. The pedestal 920 may have vertical motion 926 provided by a lifting assembly 928. A bellows 930 allows the vertical motion 926 to occur without breaking the seal of the internal process volume 904. The ICP chamber 900 may also include a controller 946. The controller 946 controls the operation of the ICP chamber 900 using a direct control or alternatively, by controlling the computers (or controllers) associated with the ICP chamber 900. In operation, the controller 946 enables data collection and feedback to optimize performance of the ICP chamber 900. In some embodiments, the controller 946 may interact with a controller 270 that controls the RF plasma sources and/or the ICP generation system 980 (which includes the split coil assembly 962 and the first RF plasma source 918 and the second RF plasma source 960). The controller 946 generally includes a Central Processing Unit (CPU) 948, a memory 950, and a support circuit 952. The CPU 948 may be any form of a general-purpose computer processor that can be used in an industrial setting. The support circuit 952 is conventionally coupled to the CPU 948 and may comprise a cache, clock circuits, input/output subsystems, power supplies, and the like. Software routines, such as used in the methods and/or apparatus as described above may be stored in the memory 950 and, when executed by the CPU 948, transform the CPU 948 into a specific purpose computer (controller 946). The software routines may also be stored and/or executed by a second controller (not shown) that is located remotely from the ICP chamber 900.

The memory 950 is in the form of computer-readable storage media that contains instructions, when executed by the CPU 948, to facilitate the operation of the semiconductor processes and equipment. The instructions in the memory 950 are in the form of a program product such as a program that implements the apparatus of the present principles. The program code may conform to any one of a number of different programming languages. In one example, the disclosure may be implemented as a program product stored on a computer-readable storage media for use with a computer system. The program(s) of the program product define functions of the aspects. Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the substrate heating system described herein, are aspects of the present principles.

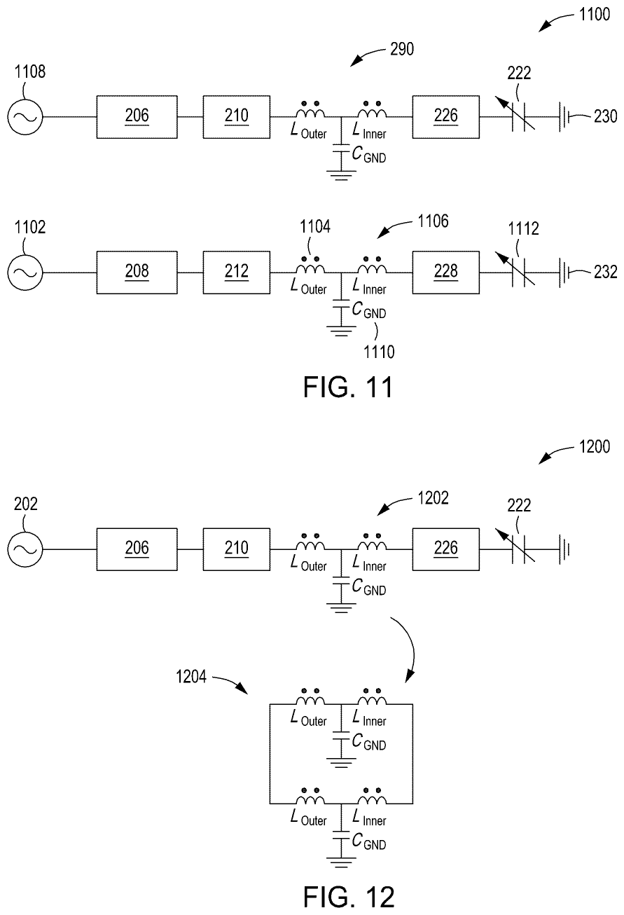

FIG. 11 depicts a schematic view of a coil energizing system 1100 according to some embodiments. In some instances where a process chamber is operating at low pressures (e.g., less than 10 mTorr, etc.), with no bias power (bias power is approximately zero), and with a low plasma striking source power (e.g., less than or equal to approximately 50 W and the like, etc.), poor pulsing window and striking performance may be overcome with the coil energizing systems of the present principles. For example, a second RF power source channel 1102 may be operated at a second frequency (e.g., 27 MHz, etc.) at a low power to generate a background plasma (e.g., energizing only an outer coil 1104 of a second split coil set 1106, etc.). A first RF power source channel 1108 at a first frequency (e.g., 13 MHz, etc.) is then pulsed to generate the main inductively coupled plasma in the process chamber. The combination improves the process operation window and performance. A ground capacitor 1110 for the second split coil set 1106 is selected based on the second frequency, and a second current divider capacitor 1112 is used to control the low power background plasma predominantly with the outer coil 1104.

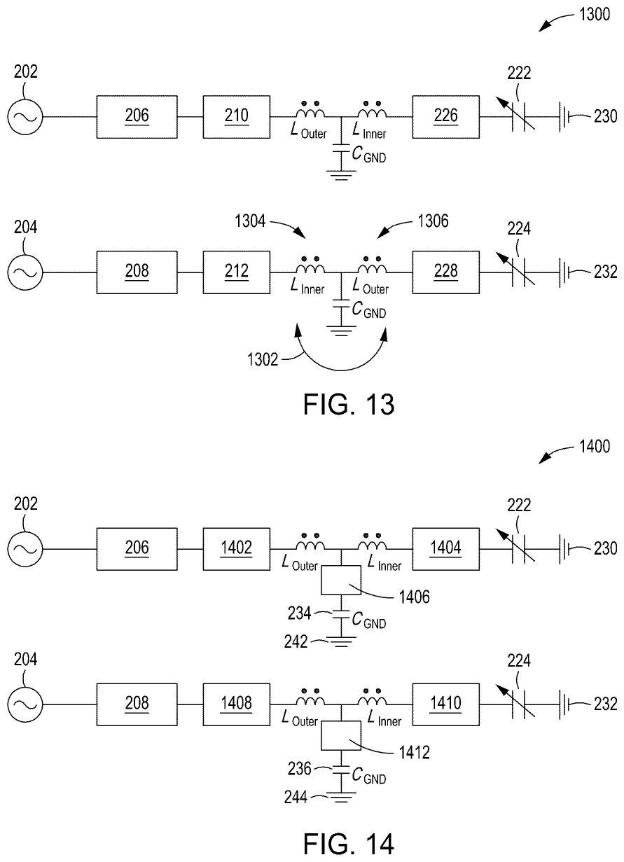

In some embodiments as depicted in the schematic views 1200 of FIG. 12, the split coil set 1202 of either RF power source channel (components for the first RF power source channel 202 depicted in FIG. 12 for example only and not meant to be limited only to the application of the first RF power source channel 202) may comprise any number of parallel inner and outer inductor pairs (e.g., two parallel pairs 1204 depicted in FIG. 12). The values and types (fixed/variable, etc.) of the current divider capacitors and the ground capacitors can be different for each RF power source channel. In some embodiments, the inner coil 1304 and the outer coil 1306 of one or more RF power source channels may have electrical connections changed, for example but not meant to be limited to, as depicted in a view 1300 of FIG. 13.

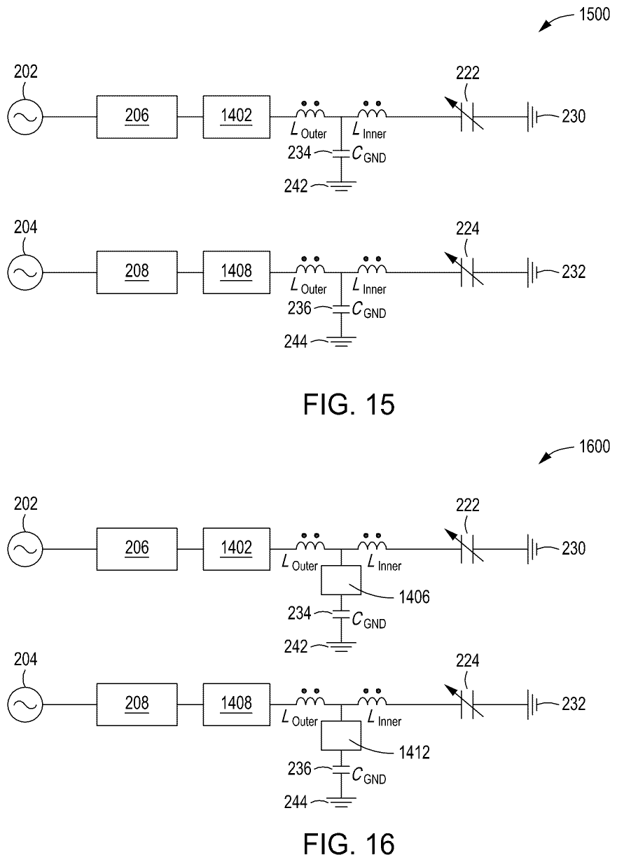

In some embodiments, one or more filters may be used for each RF power source channel and electrically interconnected in one or more positions as depicted in a view 1400 of FIG. 14. A first position 1402 of the first RF power source channel 202 may be after the first match network 206 and before the coils. A second position 1404 of the first RF power source channel 202 may be after the coils and before or after the first current divider capacitor 222. A third position 1406 of the first RF power source channel 202 may be at the connection between the coils and the first split coil ground 242, before or after the first ground capacitor 234. A first position 1408 of the second RF power source channel 204 may be after the second match network 208 and before the coils. A second position 1410 of the second RF power source channel 204 may be after the coils and before or after the second current divider capacitor 224. A third position 1412 of the second RF power source channel 204 may be at the connection between the coils and the first split coil ground 244, before or after the second ground capacitor 236. The filters provide better isolation and noise control, reduce crosstalk, and improve tunability and uniformity control. At least one filter at one of the three positions in each RF power source channel is used to block RF interference between the two channels (each filter set to block at least the frequency of the other RF power source channel frequency). For example, and not meant to be limited to, as depicted in a view 1500 of FIG. 15, a single filter is positioned in the first position of each of the RF power source channels. In a view 1600 of FIG. 16, a filter is positioned in the first position of each of the RF power source channels and also in the third position of each of the RF power source channels.

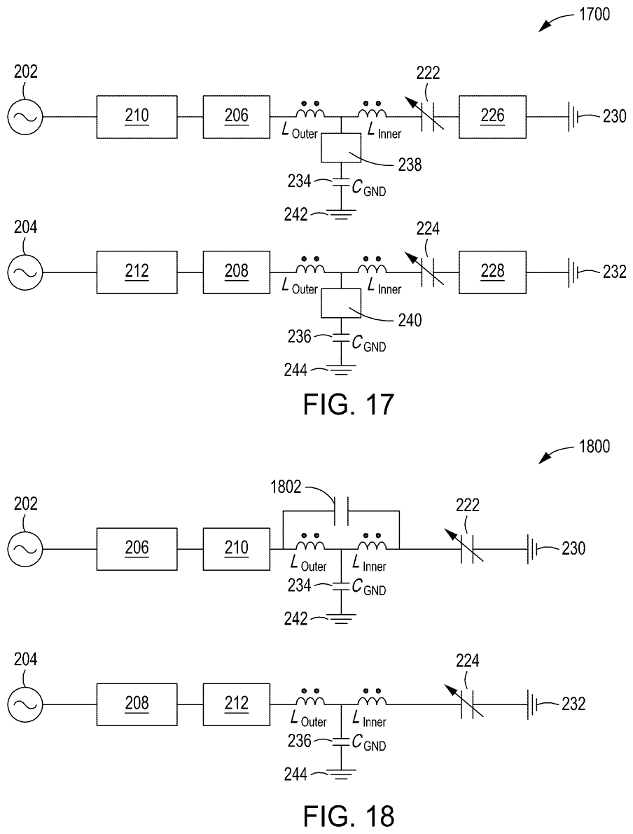

For filters that are in electrical series with other components, the filters may be positioned before or after the series components. For example, but not meant to be limited to, in a view 1700 of FIG. 17, a filter may be positioned before the match network in each RF power source channel, a filter may be positioned after the current divider capacitors and the ground in each RF power source channel, and a filter may be positioned before the ground capacitor in each RF power source channel. In some embodiments, a bridge capacitor 1802 may be positioned across the inner and outer coil sets of one RF power source channel (depicted in view 1800 of FIG. 18) or all coil sets in each of the RF power source channels (not shown).

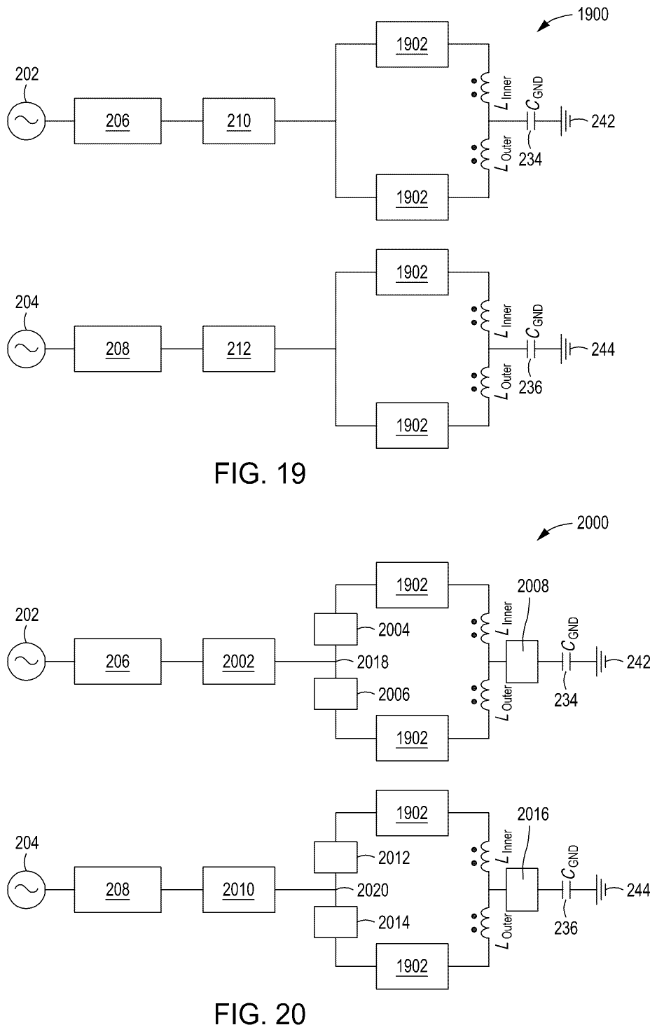

A view 1900 of FIG. 19 depicts a schematic where divider circuits 1902 are incorporated into each RF power source channel. The divider circuits 1902 may be a wire (no series components between a filter and the coils), a fixed capacitor, a variable capacitor, a capacitor and inductor in parallel, or any combination thereof for each of the divider circuits 1902 (the divider circuits 1902 may contain different components or different combinations of components, etc.). In some embodiments, one or more filters may be used for each RF power source channel and electrically interconnected in one or more positions as depicted in a view 2000 of FIG. 20. A first position 2002 of the first RF power source channel 202 may be after the first match network 206 and before the split junction 2018 of the divider circuits 1902. A second position 2004 and a third position 2006 of the first RF power source channel 202 may be after the split junction 2018 and in each leg, respectively, of the divider circuits 1902. A fourth position 2008 of the first RF power source channel 202 may be at the connection between the coils and the first split coil ground 242, before or after the first ground capacitor 234. A first position 2010 of the second RF power source channel 204 may be after the second match network 208 and before the split junction 2020 of the divider circuits 1902. A second position 2012 and a third position 2014 of the second RF power source channel 204 may be after the split junction 2020 and in each leg, respectively, of the divider circuits 1902. A fourth position 2016 of the second RF power source channel 204 may be at the connection between the coils and the second split coil ground 244, before or after the second ground capacitor 236. The filters provide better isolation and noise control, reduce crosstalk, and improve tunability and uniformity control. Electrical components, such as, for example, filters and capacitors and the like, in series may be positioned in any order in each leg of the divider circuits.

In some embodiments, the first RF power source channel 202 may be connected to a first dual output match network 2120 connected to a first shunt capacitor 2110 and two series capacitors 2114 in each leg of the divider circuits 1902 with a series filter 2102 as depicted in a view 2100 of FIG. 21. The second RF power source channel 204 may be connected to a second dual output match network 2122 connected to a second shunt capacitor 2112 and two series capacitors 2116 in each leg of the divider circuits 1902 with a series filter 2106. The divider circuits 1902 may be a wire (no series components between a filter and the coils), a fixed capacitor, a variable capacitor, a capacitor and inductor in parallel, or any combination thereof for each of the divider circuits 1902 (the divider circuits 1902 may contain different components or different combinations of components, etc.).

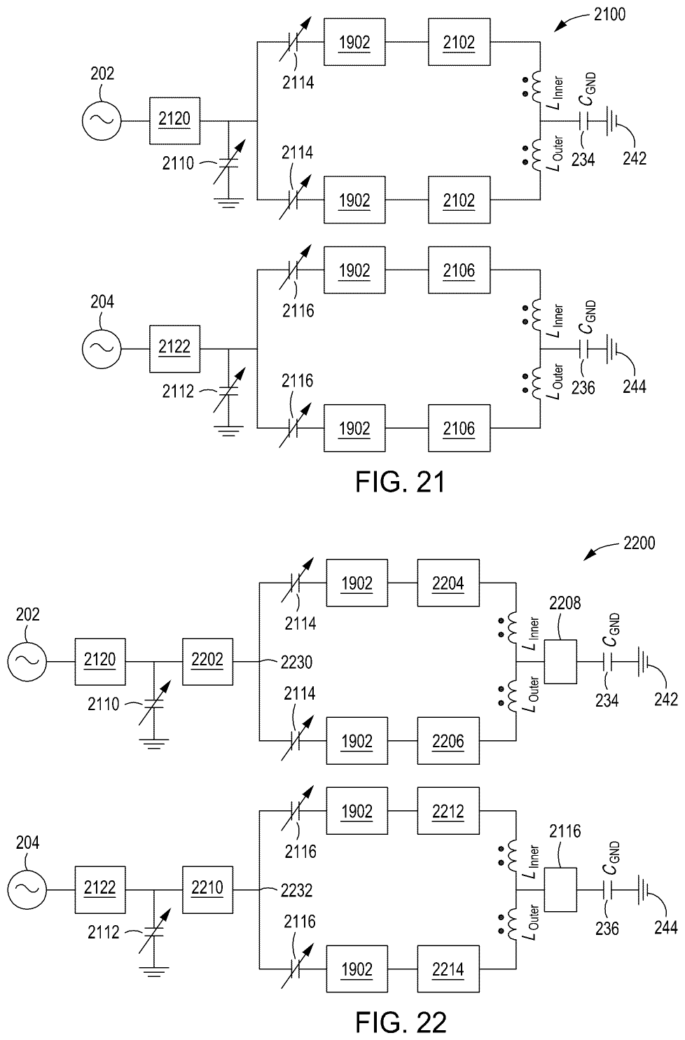

In some embodiments, one or more filters may be used for each RF power source channel and electrically interconnected in one or more positions as depicted in a view 2200 of FIG. 22. A first position 2202 of the first RF power source channel 202 may be after a first dual output match network 2120 and before the split junction 2230 of the divider circuits 1902 and the series capacitors 2114. A second position 2204 and a third position 2206 of the first RF power source channel 202 may be after the split junction 2230 and in each leg, respectively, of the divider circuits 1902. A fourth position 2208 of the first RF power source channel 202 may be at the connection between the coils and the first split coil ground 242, before or after the first ground capacitor 234. A first position 2210 of the second RF power source channel 204 may be after the second dual output match network 2122 and before the split junction 2232 of the divider circuits 1902 and the series capacitors 2116. A second position 2212 and a third position 2214 of the second RF power source channel 204 may be after the split junction 2232 and in each leg, respectively, of the divider circuits 1902. A fourth position 2216 of the second RF power source channel 204 may be at the connection between the coils and the second split coil ground 244, before or after the second ground capacitor 236. The filters provide better isolation and noise control, reduce crosstalk, and improve tunability and uniformity control. Electrical components, such as, for example, filters and capacitors and the like, in series may be positioned in any order in each leg of the divider circuits.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method of energizing a coil assembly of an inductively coupled plasma (ICP) chamber, comprising:
generating a first RF power for the ICP chamber with a first frequency to a first electrical connection of a first coil set of the coil assembly via a first match network, wherein a second electrical connection of the first coil set is connected to a ground, and wherein the coil assembly is positioned atop the ICP chamber; and
generating a second RF power for the ICP chamber with a second frequency to a third electrical connection of a second coil set of the coil assembly via a second match network, wherein a fourth electrical connection of the second coil set is connected to the ground and wherein the second frequency is the same or different from the first frequency,
wherein the first coil set has at least one first inner coil and at least one first outer coil positioned concentrically about the at least one first inner coil, wherein the at least one first inner coil and the at least one first outer coil are electrically connected in series,
wherein the second coil set has at least one second inner coil and at least one second outer coil positioned concentrically about the at least one second inner coil, wherein the at least one second inner coil and the at least one second outer coil are electrically connected in series, and
wherein the first coil set and the second coil set are each electrically connected to a different RF power source channel.

2. The method of claim 1, further comprising:
filtering the second frequency of the second RF power from the first RF power with a first RF isolation filter positioned in series between the first match network and the first electrical connection of the first coil set or between the first match network and a source of the first RF power; and
filtering the first frequency of the first RF power from the second RF power with a second RF isolation filter positioned in series between the second match network and the third electrical connection of the second coil set or between the second match network and a source of the second RF power.

3. The method of claim 1, wherein the second electrical connection is connected to the ground via a first current divider and wherein the third electrical connection is connected to the ground via a second current divider.

4. The method of claim 3, wherein a first current divider filter is positioned in electrical series between the second electrical connection of the first coil set and the ground to adjust current through the first current divider and a second current divider filter is positioned in electrical series between the fourth electrical connection of the second coil set and the ground to adjust current through the second current divider.

5. The method of claim 1, wherein a first capacitor is connected between the at least one first inner coil and the at least one first outer coil and a ground, wherein a second capacitor is connected between the at least one second inner coil and the at least one second outer coil and the ground, wherein a first ground filter is positioned in electrical series with the first capacitor of the first coil set and the ground and a second ground filter is positioned in electrical series with the second capacitor of the second coil set and the ground.

6. The method of claim 1, wherein the first coil set has a plurality of sets of series connected first inner coils and first outer coils and wherein each set of series connected first inner coils and first outer coils are connected in parallel to each other set of the plurality of sets of series connected first inner coils and first outer coils and wherein the second coil set has a plurality of sets of series connected second inner coils and second outer coils and wherein each set of series connected second inner coils and second outer coils are connected in parallel to each other set of the plurality of sets of series connected second inner coils and second outer coils.

7. The method of claim 1, wherein the at least one first inner coil of the first coil set is intertwined with the at least one second inner coil of the second coil set and the at least one first outer coil of the first coil set is intertwined with the at least one second outer coil of the second coil set.

8. The method of claim 1, wherein the first RF power is pulsed at a first power level and at a first pulse frequency and the second RF power is pulsed at a second power level and at a second pulse frequency, wherein the second power level is different from the first power level.

9. The method of claim 1, wherein the first RF power is pulsed with a first pulse at a first power level and a second pulse at a second power level different from the first power level.

10. The method of claim 9, wherein the first pulse has a first pulse width and the second pulse has a second pulse width different from the first pulse width.

11. The method of claim 1, wherein the second RF power is pulsed with a first pulse at a first power level and a second pulse at a second power level different from the first power level.

12. The method of claim 11, wherein the first pulse has a first pulse width and the second pulse has a second pulse width different from the first pulse width.

13. An apparatus for supplying RF energy to an inductively coupled plasma (ICP) chamber, comprising:
a first coil set of a coil assembly, wherein a first electrical connection of the first coil set is connected to a first RF power channel with a first frequency and a second electrical connection of the first coil set is connected to a ground, wherein the first coil set has at least one first inner coil and at least one first outer coil positioned concentrically about the at least one first inner coil and wherein the at least one first inner coil and the at least one first outer coil are electrically connected in series; and
a second coil set of the coil assembly, wherein a third electrical connection of the first coil set is connected to a second RF power channel with a second frequency and a fourth electrical connection of the second coil set is connected to the ground, wherein the second frequency of the second RF power channel is the same or different from the first frequency of the first RF power channel, wherein the second coil set has at least one second inner coil and at least one second outer coil positioned concentrically about the at least one second inner coil, wherein the at least one second inner coil and the at least one second outer coil are electrically connected in series,
and wherein the first coil set and the second coil set of the coil assembly are each configured to be electrically energized by different RF power source channels.

14. The apparatus of claim 13, further comprising:
a first RF isolation filter positioned in electrical series between the first electrical connection of the first coil set and the first RF power channel or between a first match network and the first RF power channel, wherein the first RF isolation filter is configured to pass the first frequency and block the second frequency; and
a second RF isolation filter positioned in electrical series between the third electrical connection of the second coil set and the first RF power channel or between a second match network and the second RF power channel, wherein the second RF isolation filter is configured to pass the second frequency and block the first frequency.

15. The apparatus of claim 13, further comprising:
a first current divider filter positioned in electrical series between the second electrical connection of the first coil set and the ground and configured to adjust current through a first current divider; and
a second current divider filter positioned in electrical series between the fourth electrical connection of the second coil set and the ground and configured to adjust current through a second current divider.

16. The apparatus of claim 13, further comprising:
a first ground filter positioned in electrical series with a first capacitor positioned between the at least one first inner coil and the at least one first outer coil of the first coil set and a ground; and
a second ground filter positioned in electrical series with a second capacitor positioned between the at least one second inner coil and the at least one second outer coil of the second coil set and the ground.

17. The apparatus of claim 13, wherein the at least one first inner coil of the first coil set is intertwined with the at least one second inner coil of the second coil set and the at least one first outer coil of the first coil set is intertwined with the at least one second outer coil of the second coil set.

18. The apparatus of claim 13, wherein the first RF power channel and the second RF power channel are provided by a single RF generator with a plurality of RF power channels.

19. The apparatus of claim 13, wherein the first coil set has a plurality of sets of series connected first inner coils and first outer coils and wherein each set of series connected first inner coils and first outer coils are connected in parallel to each other set of the plurality of sets of series connected first inner coils and first outer coils and wherein the second coil set has a plurality of sets of series connected second inner coils and second outer coils and wherein each set of series connected second inner coils and second outer coils are connected in parallel to each other set of the plurality of sets of series connected second inner coils and second outer coils.

20. A non-transitory, computer readable medium having instructions stored thereon that, when executed, cause a method of energizing a coil assembly of an inductively coupled plasma (ICP) chamber to be performed, the method comprising:
generating a first RF power for the ICP chamber with a first frequency to a first electrical connection of a first coil set of the coil assembly via a first match network, wherein a second electrical connection of the first coil set is connected to a ground, and wherein the coil assembly is positioned atop the ICP chamber; and
generating a second RF power for the ICP chamber with a second frequency to a third electrical connection of a second coil set of the coil assembly via a second match network, wherein a fourth electrical connection of the second coil set is connected to the ground and wherein the second frequency the same or different from the first frequency,
wherein the first coil set has at least one first inner coil and at least one first outer coil positioned concentrically about the at least one first inner coil, wherein the at least one first inner coil and the at least one first outer coil are electrically connected in series,
wherein the second coil set has at least one second inner coil and at least one second outer coil positioned concentrically about the at least one second inner coil, wherein the at least one second inner coil and the at least one second outer coil are electrically connected in series,
and wherein the first coil set and the second coil set of the coil assembly are each configured to be electrically energized by different RF power source channels.
